(19) United States
(12) Patent Application Publication
(10) Pub. No.: US 2006/0068581 A1
(43) Pub. Date: Mar. 30, 2006

(54) Method of forming via hole in resin layer

(75) Inventor: Kazutaka Kobayashi, Nagano-shi (JP)

Correspondence Address: STAAS & HALSEY LLP, SUITE 700, 1201 NEW YORK AVENUE, N.W., WASHINGTON, DC, 20005, US

(73) Assignee: SHINKO ELECTRIC INDUSTRIES CO., LTD., Nagano-shi (JP)

(21) Appl. No.: 10/537,863

(22) PCT Filed: Oct. 5, 2004
(86) PCT No.: PCT/JP04/15003

§ 371 Date: Jun. 6, 2005

(30) Foreign Application Priority Data
Oct. 6, 2003 (JP) 2003-346722

(51) Int. Cl. H01L 21/4763

(52) U.S. Cl. 438/622

(57) ABSTRACT

To reliably expose an underlying layer at a bottom surface of a via hole to form a via hole even at a resin layer including an inorganic filler. A method of forming a via hole by firing a laser beam at a resin layer (10) including an inorganic filler (12) characterized by including a first laser beam firing step of firing a (CO₂) laser beam of the infrared region at a position of said resin layer for forming a via hole so as to expel the resin (11) and said inorganic filler (12) and thereby form a hole (18) in the resin layer and a second laser beam firing step of firing a (UV-YAG) laser beam of the ultraviolet region focused at a position where the hole is formed to remove a modified layer (16) of the resin remaining at the bottom of the hole and form a via hole (20) with an underlying layer (14) exposed at its bottom.

### TECHNICAL FIELD

The present invention relates to a method of forming a via hole in a resin layer able to be applied when forming a via hole in a resin layer of a multilayer circuit board.

### BACKGROUND ART

A multilayer circuit board is formed by stacking interconnect patterns through epoxy resins or other resin layers having electrical insulating characteristics. By providing vias so as to pass through the resin layers in the thickness direction, layers of the interconnect patterns are electrically connected. There are several methods for forming a via, but the general practice is to laminate an uncured epoxy resin or other resin film to form a resin layer, fire a CO₂ laser beam or UV-YAG laser beam at the resin layer to form a via hole so that the underlying layer of an interconnect pattern is exposed at the bottom surface, then plate the inside surface of the via hole to form a conductive layer electrically connected with the interconnect pattern exposed at the bottom surface of the via hole.

When using the above CO₂ laser processing to form a via hole in a resin layer, residue thinly remains at the bottom surface at the inside of the via hole, so after the laser processing, desmearing is performed to chemically remove the residue using a sodium permanganate solution or a potassium permanganate solution.

Further, when forming a via hole by a UV-YAG laser rather than a CO₂ laser, since a UV-YAG laser beam is a beam of the ultraviolet region, the C—C bonds forming the resin are cleaved and therefore it is possible to obtain a bottom surface inside the via hole as a surface without any residue.

Note that as the method for removing residue formed at the bottom surface of a via hole or around the opening of a via hole when processing a via hole, rather than using chemical processing, the method of firing a pulse laser beam (see Japanese Unexamined Patent Publication (Kokai) No. 2000-197987) or the method of firing a green laser beam (see Japanese Unexamined Patent Publication (Kokai) No. 11-333585) has been proposed.

However, when using CO₂ laser processing to form a via hole in a resin layer, when the resin layer is comprised of an epoxy resin, it is relatively easy to remove residue deposited at the bottom surface of the via hole by desmearing after the laser processing. However, a resin material forming an insulating layer preferably is one having a low water absorption rate with less fluctuations in electrical properties due to temperature and humidity than the conventionally used epoxy resin and having a low dielectric constant and low dielectric loss tangent. Further, a resin material containing an inorganic filler with a band gap of 3 to 4 eV has small fluctuation in electrical properties due to changes in temperature and humidity and a relatively high dielectric constant, so is preferable as a dielectric layer of a capacitor formed between layers of a multilayer circuit board. However, a low dielectric constant and low dielectric loss tangent resin has the problem of difficult removal of the residue produced at the time of laser processing by desmearing.

A board formed using a resin material containing an inorganic filler with a band gap of 3 to 4 eV has the problem that it cannot be effectively formed with a via hole simply by the method of firing a laser beam using a CO₂ laser or UV-YAG laser and therefore suffers from unreliable electrical conduction at the via part and the problem that the processing for forming a via hole takes a long time and therefore the method cannot be employed for producing actual products.

The inventors analyzed in detail the formation of via holes in a resin layer including inorganic filler using a laser beam and clarified the causes of poor conduction and thereby completed the present invention. That is, the object of the present invention is to provide a method of forming a via hole enabling formation of a via hole while reliably exposing the underlying layer at the bottom of the via hole and able to be utilized when producing a multilayer circuit board etc. having a resin layer including inorganic filler.

The inventors discovered that when the inorganic filler having a band gap of 3 to 4 eV included in the resin layer absorbs ultraviolet laser light, it changes, melts, and remains on the underlying layer. If the resin absorbs the ultraviolet light, the C—C bonds are cleaved and the expulsion phenomenon becomes completely different. The present invention was created based on this discovery and is characterized by provision of the following configuration.

That is, there is provided with a method of forming a via hole by firing a laser beam in a resin layer including an inorganic filler, characterized by including a first laser beam firing step of firing a laser beam of the infrared region at a position of the resin layer for forming a via hole so as to expel the resin and the inorganic filler and thereby form a hole in the resin layer and a second laser beam firing step of firing a laser beam of the ultraviolet region focused at a position where the hole is formed to remove a modified layer of the resin remaining at the bottom of the hole and form a via hole with an underlying layer exposed at its bottom.

Note that in the present description, the “infrared region” means the wavelength region from a lower limit of 800 nm to the longer wavelength side, while the “ultraviolet region” means the wavelength region from an upper limit of 400 nm to the shorter wavelength side.

Further, it is effective to use a CO₂ laser in the first laser beam firing step and use a UV-YAG laser in the second laser beam firing step.

Further, the invention is characterized in that the resin layer includes at least one type of inorganic filler among barium titanate, titanium oxide, strontium titanate, and barium-strontium titanate and that the resin layer includes an inorganic filler with a dielectric constant of 30 to 15000. Alternatively, it is characterized in that the resin layer includes an inorganic filler having a band gap of 3 to 4 eV.

According to the present invention, when forming a via hole by firing a laser beam at a resin layer, by dividing the laser beam firing step into a first laser beam firing step for firing a laser beam of the infrared region and a second laser beam firing step for firing a laser beam of the ultraviolet region, even if the resin layer contains inorganic filler with a band gap of 3 to 4 eV, it becomes possible to reliably form a via hole in a short time. Therefore, the remarkable effect is exhibited that it is possible to suitably utilize this when producing a multilayer circuit board provided with an insulating layer having a specific function.

### BRIEF DESCRIPTION OF DRAWINGS

FIG. 1(a) to FIG. 1(d) are explanatory views of a method of forming a via hole according to the present invention.

FIG. 2(a) to FIG. 2(d) are explanatory views of a method of forming a via hole using a UV-YAG laser in a resin layer including an inorganic filler.

FIG. 3(a) and FIG. 3(b) are explanatory views of a method of forming a via hole using a CO₂ laser in a resin layer including an inorganic filler.

FIG. 4 shows a via hole in Comparative Examples 1 and 2, a Reference Example, and Examples 1 to 3.

### BEST MODE FOR CARRYING OUT THE INVENTION

Below, preferred embodiments of the present invention will be explained in detail with reference to the attached drawings while comparing Comparative Examples 1 to 3 and Examples 1 to 3.

### COMPARATIVE EXAMPLE 1

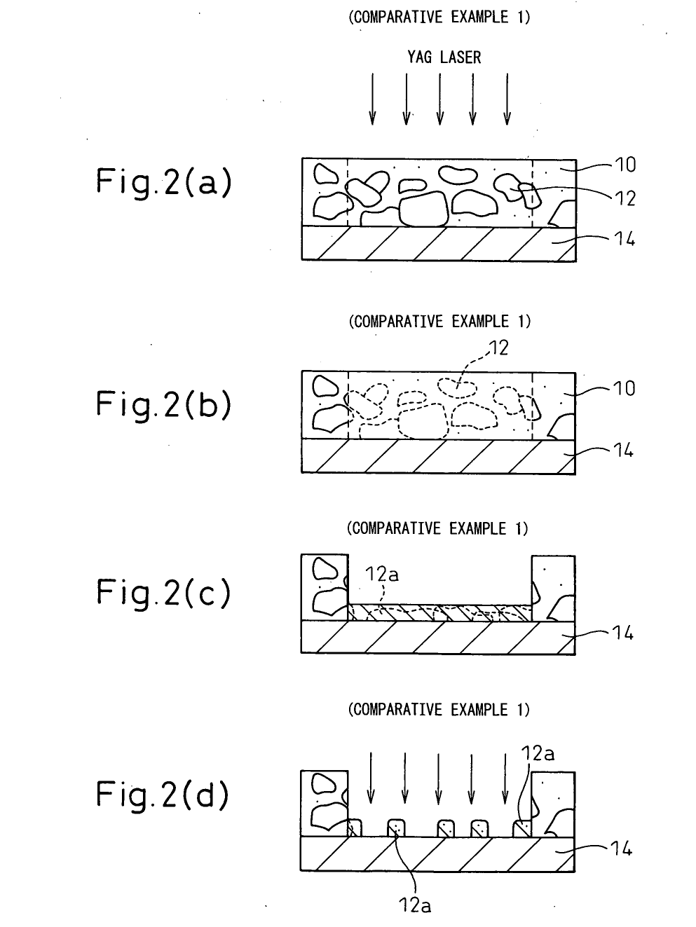

FIG. 2(a) to FIG. 2(d) show the case of forming a via hole using a UV-YAG laser in a resin layer 10 including an inorganic filler 12 having a band gap of 3 to 4 eV as a comparative example of the present invention.

FIG. 2(a) shows the state of firing a laser beam at a resin layer 10 comprised of polyphenylene ether using a UV-YAG laser. Note that the resin layer 10 is one comprised of a resin in which an inorganic filler 12 comprised of titanium oxide is included. If firing a laser beam at a resin layer 10 including an inorganic filler 12 in this way, the inorganic filler 12 will absorb the laser beam, heat up, and melt (FIG. 2(b)). On the other hand, the resin will be expelled from the resin layer 10 by being fired upon by the laser beam, so the surface of the underlying layer 14 will have an inorganic layer 12a of molten inorganic filler 12 left at it (FIG. 2(c)).

In the method of forming a via hole in Comparative Example 1, the laser processing residue at the surface of the underlying layer is removed by desmearing using a sodium permanganate solution, potassium permanganate solution, etc.

However, the inorganic layer 12a remaining at the surface of the underlying layer 14 in the state of FIG. 2(c) cannot be completely removed by desmearing.

Therefore, a laser beam is further fired to remove the inorganic layer 12a remaining at the surface of the underlying layer 14. This procedure inputs 40 mJ of energy per via hole and causes local heating to 1000° C. or more.

The method shown in Comparative Example 1 requires a long processing time and cannot be said to be a method realistic as a method of forming a via hole in a resin layer 10 including an inorganic filler 12. Further, the inorganic layer 12a is not completely removed and the reliability of conductivity is low.

### COMPARATIVE EXAMPLE 2

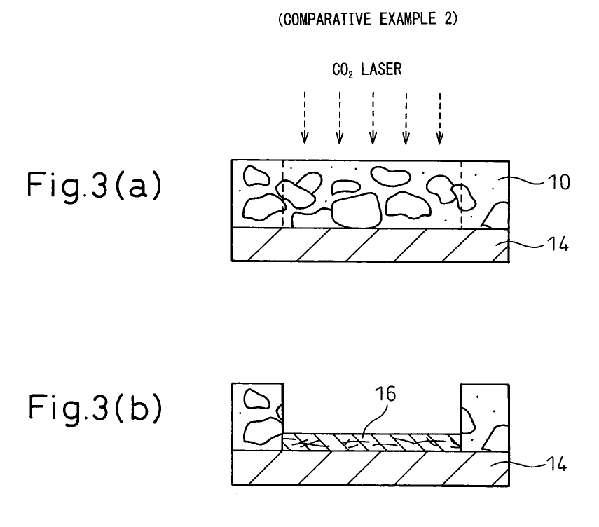

FIG. 3(a) and FIG. 3(b) show the case of forming a via hole using a CO₂ laser in a resin layer 10 including an inorganic filler 12 having a band gap of 3 to 4 eV comprised of titanium oxide as a comparative example of the present invention. As the resin layer 10, a polyphenylene ether resin was used. This resin is a resin which will not dissolve much at all due to desmearing. As a resin which will not dissolve much at all by desmearing in this way, there are a cycloalkane resin, polystyrene, polyethylene, liquid crystal polymer, etc.

FIG. 3(a) shows the state of firing a CO₂ laser beam at a resin layer 10. A CO₂ laser fires three laser pulses of 0.8 mJ per via hole for a total of 2.4 mJ. The wavelength of the CO₂ laser is 9.4 μm or in the infrared region. Titanium oxide of the inorganic filler 12 does not absorb almost any light of this wavelength. Therefore, firing a laser beam from a CO₂ laser expels the inorganic filler 12 along with the resin. However, if firing a CO₂ laser to expel the inorganic filler 12 and resin, the surface of the underlying layer 14 is left with a modified layer 16 of the modified resin (FIG. 3(b)).

It was attempted to remove the modified layer 16 by desmearing using a conventional sodium permanganate solution etc., but the desmearing could not remove the modified layer 16. This modified layer (resin smear) 16 is believed to result from the laser beam being fired to the resin layer 10 resulting in the resin being modified to something which cannot be removed by a CO₂ layer and cannot be removed even by desmearing.

The method shown in Comparative Example 2 also cannot be a realistic method of forming a via hole in a resin layer 10 including an inorganic filler 12.

### REFERENCE EXAMPLE

A resin layer comprised of polyphenylene ether using as an inorganic filler silica (SiO₂) having a band gap of about 9 eV was formed with a via hole using a UV-YAG laser with a wavelength of 355 nm. The energy of the laser beam was 2 mJ per via hole. Firing the UV-YAG laser causes the resin to be dispersed, expelled, and removed. A silica filler has a band gap of 9 eV, so firing of the UV-YAG laser does not cause any change in the silica filler, expels and removes the silica together with the resin, and exposes the underlying layer at the location where the laser beam is fired.

### EXAMPLE 1

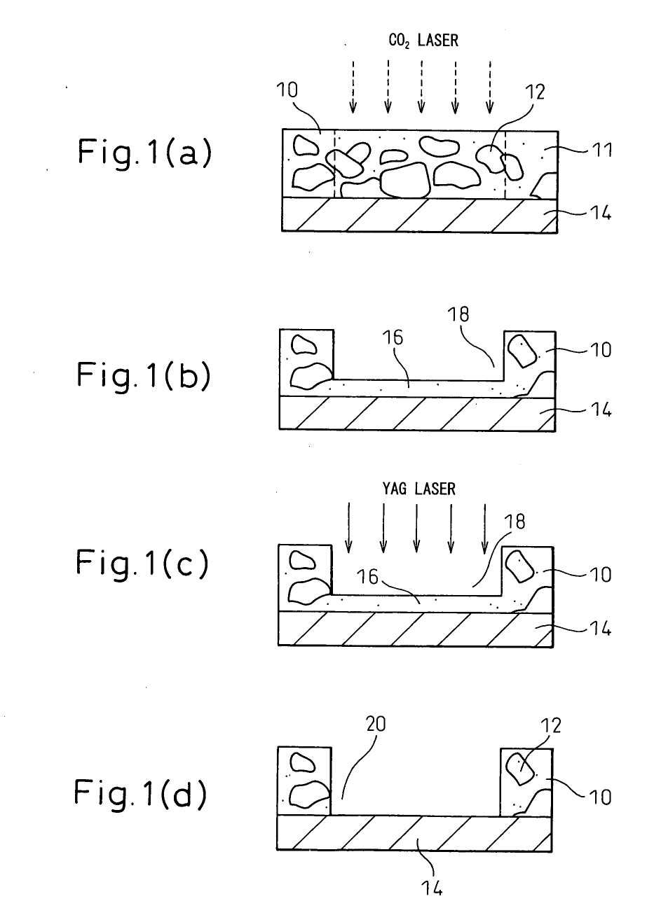

FIG. 1(a) to FIG. 1(d) are explanatory views of a method of forming a via hole in a resin layer by the method of the present invention (Example 1). Reference numeral 10 is a resin layer, while 14 is an underlying layer. The resin layer 10 includes an inorganic filler 12, so in Example 1, a via hole is formed in a resin layer 10 including titanium oxide as an inorganic filler 12 with a band gap of 3 to 4 eV. As the resin 11 forming the resin layer 10, a polyphenylene ether (PPE) resin was used. The PPE resin is a resin difficult to remove by desmearing, while the inorganic filler 12 is mixed in by a weight ratio with the resin 11 of 1:1. Note that the rate of mixture of the inorganic filler in the present invention is not limited to the rate in Example 1.

In Example 1 as well, a laser beam is fired at the resin layer in the same way as the conventional method (Comparative Examples 1 to 3) to remove the resin at the location for forming the via hole. In Example 1, the operation for firing a laser beam at the resin layer 10 is divided into a first laser beam firing step for firing a laser beam from a CO₂ laser and a second laser beam firing step for firing a laser beam from a UV-YAG laser.

FIG. 1(a) shows the state of firing the laser beam focused on a position of the resin layer 10 for forming the via hole using a CO₂ laser (wavelength 9.4 μm) as a first laser beam firing step.

The thickness of the resin layer in Example 1 was 40 μm. As the condition for firing the first laser comprised of the CO₂ laser, it fired a 0.8 mJ laser pulse three times per via hole for a total of 2.4 mJ. Note that the firing conditions of the CO₂ laser must be changed according to the content of the inorganic filler or the thickness of the resin layer. The second laser comprised of the UV-YAG laser had a wavelength of 355 nm and fired 0.1 mJ per via hole. Note that the firing condition of the UV-YAG laser may be suitably changed in accordance with the thickness of the resin residue. The present invention is not limited to the firing conditions in Example 1.

If firing a laser beam at the resin layer 10 using a CO₂ laser, the inorganic filler 12 is expelled and removed along with the resin 11 at the location where the laser beam is fired. The inorganic filler 12 comprised of titanium oxide does not absorb light of the wavelength of the CO₂ laser, so even if firing a laser beam, the titanium oxide is not excited in terms of electronic structure or melted. Therefore, it is possible to easily expel and remove the inorganic filler 12 along with the resin.

The first laser beam firing step is meant to expel and remove the inorganic filler 12 along with the resin 11. The characterizing point in this step is to select as a laser source a laser beam of a wavelength which the inorganic filler 12 forming part of the resin layer 10 does not absorb.

The titanium oxide used as the inorganic filler 12 in Example 1 has a band gap of about 3 eV and does not absorb a CO₂ laser beam. In the present invention, in the same way as the titanium oxide in Example 1, it is possible to use any suitable material as an inorganic filler 12 so long as it does not absorb a CO₂ laser beam.

If using a CO₂ laser to fire a laser beam at the resin layer 10 and expel the inorganic filler 12 together with the resin 11, as shown in FIG. 1(b), a hole 18 is formed in the resin layer 10 at the location of formation of the via hole. At the bottom of the inside of the hole 18, a modified layer 16 of the modified resin material remains to a thickness of 0.05 to 1.0 μm. The action of the modified layer 16 of the modified resin material at the bottom surface at the inside of the hole 18 thinly remaining is the exactly the same action as the case of Comparative Example 2 shown in FIG. 3(a) and FIG. 3(b).

In Example 1, as the second laser beam firing step, next a UV-YAG laser is used to fire a laser beam focused at the position of the hole 18 formed at the previous step (FIG. 1(c)). If firing a laser beam focused at the position of the hole 18, the modified layer 16 remaining at the surface of the underlying layer 14 is cleanly removed at the location at which the laser beam is fired and the underlying layer 14 is exposed at the bottom of the hole 18. This is because the modified layer is mainly comprised of C—C bonds and firing of the laser beam from the UV-YAG laser cleaves the C—C bonds.

Further, as shown in FIG. 1(d), it is possible to form in the resin layer 10 a via hole 20 where the surface of the underlying layer 14 is exposed at the bottom. In the circuit board, the underlying layer 14 is comprised of interconnect patterns comprised of a conductor layer of copper etc.

### EXAMPLE 2

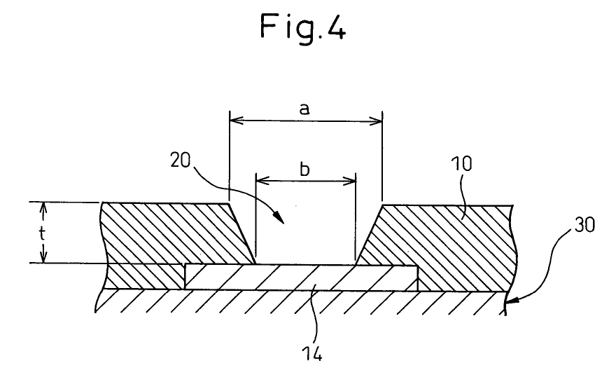

The diameter of the via hole 20 to be formed in the above Example 1 was changed. That is, in FIG. 4 showing the diameter of the via hole, in Example 1, the diameter a of the via hole 20 was made 90 μm and the diameter b of the bottom was made 60 μm (same in Comparative Examples 1 and 2, Reference Example, and later explained Example 3), while in Example 2, the diameter a of the top of the via hole 20 was made 150 μm and the diameter b of the bottom was made 120 μm. Along with this, for the firing condition of the laser beam fired, in particular the amount fired, the first laser comprised of the CO₂ laser fired a 1.0 mJ laser pulse four times per via hole for a total of 4.0 mJ. On the other hand, the second laser comprised of the UV-YAG laser had a wavelength of 355 nm or the same as Example 1, but fired 0.6 mJ per via hole.

The rest of the conditions are exactly the same as in Example 1.

### EXAMPLE 3

In Example 3, the diameter of the via hole 20 to be formed is the same as Example 1, but the UV-YAG laser used as the second laser is not one having a wavelength 355 nm used in Examples 1 and 2, but one having a wavelength of 266 nm.

The rest of the conditions are exactly the same as in Example 1.

### COMPARISON BETWEEN COMPARATIVE EXAMPLES AND EXAMPLES OF INVENTION

The following table 1 shows the results of comparison of Comparative Examples 1 and 2, Reference Example, and Examples 1 to 3. FIG. 4 shows a thickness t of a resin layer at a part forming a via hole 20 to be formed, a diameter a of the top of the via hole 20, and a diameter b of the bottom

TABLE 1
Comparison of Comparative Examples 1 and 2, Reference Example, and Examples 1 to 3

| | | | Via hole | | Average | | | Amount of | |
|---|---|---|---|---|---|---|---|---|---|
| | | Thickness | diameter (see | | filler | | Type of laser | laser fired | Quality |
| | | of resin | following | Type of | particle | Amount of | (laser | (per via | result of |
| | Type of resin | layer (6) | figure) | filler | size | filler | wavelength) | hole) | via pad |
| Comp. | Polyphenylene | 40 μm | a: 90 μm | Titanium | 3 μm | Filler:resin = 1:1 | UV-YAG | 40 mJ | Residue |
| Ex. 1 | ether | | b: 60 μm target | oxide | | | (355 nm) | | derived |
| | | | | | | | | | from |
| | | | | | | | | | inorganic |
| | | | | | | | | | filler |
| Comp. | Polyphenylene | 40 μm | a: 90 μm | Titanium | 3 μm | Filler:resin = 1:1 | CO₂ (9.4 μm) | 0.8 mJ × 3 | Residue |
| Ex. 2 | ether | | b: 60 μm target | oxide | | | | pulses | derived |
| | | | | | | | | | from resin |
| Ref. | Polyphenylene | 40 μm | a: 90 μm | Silica | 4 μm | Filler:resin = 1:1 | UV-YAG | 2.0 mJ | Good |
| Ex. | ether | | b: 60 μm | | | | (355 nm) | | |
| Ex. 1 | Polyphenylene | 40 μm | a: 90 μm | Titanium | 3 μm | Filler:resin = 1:1 | CO₂ (9.4 μm) | 0.8 mJ × 3 | Good |
| | ether | | b: 60 μm | oxide | | | | pulses | |
| | | | | | | | UV-YAG | 0.1 mJ | |
| | | | | | | | (355 μm) | | |
| Ex. 2 | Polyphenylene | 40 μm | a: 150 μm | Titanium | 3 μm | Filler:resin = 1:1 | CO₂ (9.4 μm) | 1.0 mJ × 4 | Good |
| | ether | | b: 120 μm | oxide | | | | pulses | |
| | | | | | | | UV-YAG | 0.6 mJ | |
| | | | | | | | (355 nm) | | |
| Ex. 3 | Polyphenylene | 40 μm | a: 90 μm | Titanium | 3 μm | Filler:resin = 1:1 | CO₂ (9.4 μm) | 0.8 mJ × 3 | Good |
| | ether | | b: 60 μm | oxide | | | | pulses | |
| | | | | | | | UV-YAG | 1.0 mJ | |
| | | | | | | | (266 nm) | | |

As will be understood from Table 1, in each of Examples 1 to 3, the quality of the via holes on the pads after formation of the via holes 20, that is, the copper interconnect patterns of the circuit board forming the underlying layer 14, was good.

In Examples 1 to 3, the UV-YAG laser has the action of cleaning and removing the modified layer 16 remaining deposited on the bottom of the inside of the hole 18 by the first laser firing step and exposing the underlying layer 14 at the bottom of the inside of the via hole 20.

The UV-YAG laser used in Examples 1 and 2 is one with a wavelength of 355 nm (in Example 3, 266 nm) and emits a laser beam with a wavelength absorbed by the titanium oxide used as the inorganic filler 12, but at the modified layer 16 remaining at the surface of the underlying layer 14, the inorganic filler 12 is almost completely removed at the first laser beam firing step, so by utilizing the UV-YAG laser beam expelling the resin, it becomes possible to effectively remove the modified layer 16.

When utilizing a UV-YAG laser beam to remove the modified layer 16, it is possible to cleanly remove the modified layer 16 from the surface of the underlying layer 14. There is no need for desmearing after the second laser beam firing step.

According to the method of forming a via hole of the present invention as represented by Examples 1 to 3, there is the advantage that it is possible to form a via hole by just dry processing.

Note that in addition to a PPE resin, the invention may be similarly applied to the case of use of a cycloalkane resin, a polyethylene resin, a polystyrene resin, a liquid crystal polymer, or other resin resistant to dissolution in desmearing.

The method of forming a via hole according to the present invention can be preferably used for the case of forming a circuit board provided with an insulating layer including inorganic filler having a band gap of 3 to 4 eV. That is, when the specific insulating layer is comprised of an insulating layer including organic filler such as explained above, it is sufficient to fire a laser beam from a CO₂ layer and fire a laser beam from a UV-YAG laser at the insulating layer to form a via hole and form a via electrically connecting layers of interconnect patterns.

The present invention will be explained with reference to the attached drawings by comparing Examples 1 to 3 with Comparative Examples 1 and 2 and a Reference Example, but the present invention is not limited to the above examples and may be modified, revised, etc. in various ways in the range not outside the spirit of the present invention.

For example, in Examples 1 to 3, a CO₂ laser was used in the first laser beam firing step for expelling the inorganic filler 12 along with the resin 11, but the first laser beam firing step is meant for utilizing a laser beam of a wavelength range with no light absorption by the inorganic filler 12 to expel the inorganic filler 12 along with the resin 11. So long as being a laser beam of such a wavelength region, the laser source is not limited to a CO₂ laser. Further, the second laser beam firing step is meant for removing the modified layer 16 of the resin smear remaining at the surface of the underlying layer 14. By utilizing a laser beam having a wavelength of the ultraviolet region such as a UV-YAG laser, it is possible to suitably remove the modified layer 16 and form a via hole 20.

### INDUSTRIAL APPLICABILITY

As explained above, according to the present invention, when forming a via hole by firing a laser beam at a resin layer, by dividing the laser beam firing step into a first laser beam firing step for firing a laser beam of the infrared region and a second laser beam firing step for firing a laser beam of the ultraviolet region, even if the resin layer contains inorganic filler with a band gap of 3 to 4 eV, it becomes possible to reliably form a via hole in a short time. Therefore, it is possible to suitably utilize this when producing a multilayer circuit board provided with an insulating layer having a specific function such as use as a dielectric layer of a capacitor.

1. A method of forming a via hole by firing a laser beam in a resin layer including an inorganic filler, said method of forming a via hole characterized by including:
a first laser beam firing step of firing a laser beam of the infrared region at a position of said resin layer for forming a via hole so as to expel the resin and said inorganic filler and thereby form a hole in said resin layer and a second laser beam firing step of firing a laser beam of the ultraviolet region focused at a position where said hole is formed to remove a modified layer of the resin remaining at the bottom of said hole and form a via hole with an underlying layer exposed at its bottom.

2. A method of forming a via hole as set forth in claim 1, characterized by:
using a CO₂ laser in the first laser beam firing step and using a UV-YAG laser in the second laser beam firing step.

3. A method of forming a via hole as set forth in claim 1, characterized in that said resin layer includes at least one type of inorganic filler among barium titanate, titanium oxide, strontium titanate, and barium-strontium titanate.

4. A method of forming a via hole as set forth in claim 1, characterized in that said resin layer includes an inorganic filler with a dielectric constant of 30 to 15000.

5. A method of forming a via hole as set forth in claim 1, characterized in that said resin layer includes an inorganic filler having a band gap of 3 to 4 eV.
